(19) United States
(12) Patent Application Publication
(10) Pub. No.: US 2013/0005056 A1
(43) Pub. Date: Jan. 3, 2013

(54) METHOD AND APPARATUS FOR PROCESSING WAFER EDGE PORTION

(75) Inventors: Duk Sik Kim, Cheonan-si (KR); Wonkwon Shin, Cheongju-si (KR)

(73) Assignee: SEMES CO., LTD., Cheonan-si (KR)

(21) Appl. No.: 13/537,861

(22) Filed: Jun. 29, 2012

(30) Foreign Application Priority Data
Jun. 30, 2011 (KR) 10-2011-0064991
Oct. 6, 2011 (KR) 10-2011-0101702

(51) Int. Cl. G01N 21/956; H01L 21/268; G03B 27/58; H01L 21/66

(52) U.S. Cl. 438/16; 356/237.4; 250/208.1; 355/27; 257/E21.53

(57) ABSTRACT

Provided is a method for processing a wafer edge portion using photolithograph equipment. The method includes placing a wafer on a support plate, inspecting a bead removal state of an edge portion of the wafer placed on the support plate, and exposing the edge portion of the wafer placed on the support plate to light. The inspecting of the bead removal state is performed by capturing first images from the wafer placed on the support plate and inspecting the first images.

### CROSS-REFERENCE TO RELATED APPLICATIONS

This U.S. non-provisional patent application claims priority under 35 U.S.C. §119 of Korean Patent Application Nos. 10-2011-0064991, filed on Jun. 30, 2011, and 10-2011-0101702, filed on Oct. 6, 2011, the entire contents of which are hereby incorporated by reference.

### BACKGROUND OF THE INVENTION

The present invention disclosed herein relates to photolithography equipment, and more particularly, to a method and apparatus for processing a wafer edge portion.

Generally, semiconductor devices are manufactures through processes such as: a deposition process for forming a layer on a wafer; a chemical mechanical polishing process for planarization of the layer; a photolithography process for forming a photoresist pattern on the layer; an etch process for forming the layer into a pattern having electric characteristics by using the photoresist pattern; an ion implantation process for implanting ions in predetermined regions of the wafer; a cleaning process for removing contaminants from the wafer; and an inspection process for inspecting a surface of the wafer where the layer or pattern is formed or the composition or concentration of the layer.

The photolithography process is performed to form a photoresist pattern on a semiconductor wafer formed of silicon. The photolithography process includes: a coating and soft baking process for forming a photoresist layer on a wafer; an exposing and developing process for forming the photoresist layer into a photoresist pattern; an edge bead removal (EBR) process and an edge exposure of wafer (EEW) process for removing an edge portion of the photoresist layer or pattern; and a hard baking process for stabilizing and densifying the photoresist pattern.

The EBR process and the EEW process are performed to remove an edge portion of a photoresist layer or pattern, that is, a portion of a photoresist layer or pattern formed on an edge portion of a wafer because contaminants can be generated as the edge portion of the photoresist layer or pattern is separated in a later process using the photoresist layer or pattern.

However, in existing photolithography equipment, the progress state of an EBR or EEW process cannot be evaluated.

### SUMMARY OF THE INVENTION

The present invention provides a method and apparatus for processing a wafer edge portion to check the results of an edge bead removal (EBR) process and an edge exposure of wafer (EEW) process.

The present invention is not limited to those mentioned above, and the present invention will be apparently understood by those skilled in the art through the following description.

Embodiments of the present invention provide methods for processing a wafer edge portion, the methods including: placing a wafer on a support plate; inspecting a bead removal state of an edge portion of the wafer placed on the support plate; and exposing the edge portion of the wafer placed on the support plate to light, wherein the inspecting of the bead removal state is performed by capturing first images from the wafer placed on the support plate and inspecting the first images.

In some embodiments, the methods may further include inspecting an edge exposure state of the wafer placed on the support plate after the exposing of the edge portion of the wafer, wherein the inspecting of the edge exposure state may be performed by capturing second images from the wafer placed on the support plate and inspecting the second images.

In other embodiments, the first images may be continuously captured using an imaging camera fixed to a predetermined position while the wafer placed on the support plate is rotated once.

In still other embodiments, the first images may be discontinuously captured using an imaging camera fixed to a predetermined position while the wafer placed on the support plate is rotated once.

In even other embodiments, the imaging camera may be an area camera capable of capturing images by an area scan method.

In yet other embodiments, the inspecting of the bead removal state may be performed by detecting particles and measuring a width of a bead removal region using the first images.

In still other embodiments of the present invention, there are provided methods for processing a wafer edge portion, the methods including: removing beads from an edge portion of a wafer; inspecting a bead removal state of the edge portion of the wafer; exposing the edge portion of the wafer to light; and inspecting an exposed state of the edge portion of the wafer, wherein the inspecting of the bead removal state, the exposing of the edge portion, and the inspecting of the exposed state are performed using the same apparatus.

In some embodiments, the inspecting of the bead removal state may be performed by obtaining a first image from the wafer and inspecting the first image, and the inspecting of the exposed state may be performed by obtaining a second image from the wafer and inspecting the second image.

In even other embodiments of the present invention, there are provided methods for processing a wafer edge portion, the methods including: placing a wafer on a support plate; and inspecting a bead removal state of an edge portion of the wafer placed on the support plate, wherein the inspecting of the bead removal state is performed by capturing a first image from the edge portion of the wafer placed on the support plate and inspecting the first image.

In some embodiments, the methods may further include exposing the edge portion of the wafer placed on the support plate to light after the inspecting of the bead removal state.

In other embodiments, the methods may further include inspecting an edge exposure state of the wafer placed on the support plate after the exposing of the edge portion of the wafer.

In even other embodiments, the inspecting of the edge exposure state may be performed by photographing the wafer placed on the support plate to obtain a second image different from the first image and inspecting the second image.

In yet other embodiments of the present invention, there are provided apparatuses for exposing a wafer edge portion to light, the apparatuses including: a support plate configured to support a wafer; an eccentricity detecting device configured to detect eccentricity of the wafer placed on the support plate; an imaging device configured to capture first images from an edge portion of the wafer placed on the support plate; an ultraviolet radiation device configured to irradiate the edge portion of the wafer with an ultraviolet ray; and an image process device configured to receive the first images from the imaging device so as to detect a width of a bead removal region.

In some embodiments, the imaging device may discontinuously capture the first images from the edge portion of the wafer while the wafer is rotated.

In other embodiments, the eccentricity detecting device may include a charge coupled device (CCD), and the imaging device may include an area camera configured to capture images by an area scan method.

In further embodiments of the present invention, wafer processing apparatuses including: an index part including a load port and an index robot, the load port being configured to receive a wafer-containing cassette; a process part connected to the index part, the process part including a coating process part for applying photoresist to a wafer and a developing process part for developing the wafer after an exposure process; an interface part configured to carry a wafer between the process part and an exposure device configured to perform an exposure process on a wafer; and an edge exposure unit configured to expose an edge portion of a wafer to light and inspect a bead removal state of the edge portion of the wafer.

In some embodiments, the edge exposure unit may be disposed at the interface part or the process part.

In other embodiments, the edge exposure unit may include: a support plate configured to support a wafer; an eccentricity detecting device configured to detect eccentricity of the wafer placed on the support plate; an imaging device configured to capture first images from an edge portion of the wafer placed on the support plate; an ultraviolet radiation device configured to irradiate the edge portion of the wafer with an ultraviolet ray; and an image process device configured to receive the first images from the imaging device so as to detect a width of a bead removal region.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a perspective view illustrating photolithography equipment used in a wafer processing method according to an embodiment of the present invention;

FIG. 2 is a view illustrating a coating process part of the photolithography equipment of FIG. 1;

FIG. 3 is a view illustrating a developing process part of the photolithography equipment of FIG. 1;

FIG. 4 is a side view illustrating an edge exposure unit;

FIG. 5 is a plan view illustrating the edge exposure unit; and

FIG. 6 is a flowchart for explaining a method for exposing a wafer edge portion.

### DETAILED DESCRIPTION OF PREFERRED EMBODIMENTS

A method for exposing a wafer edge portion using photolithography equipment will now be explained with reference to the accompanying drawings according to exemplary embodiments of the present invention. In the drawings, like reference numerals denote like elements throughout. Moreover, detailed descriptions related to well-known functions or configurations will be ruled out in order not to unnecessarily obscure subject matters of the present invention.

### EMBODIMENT

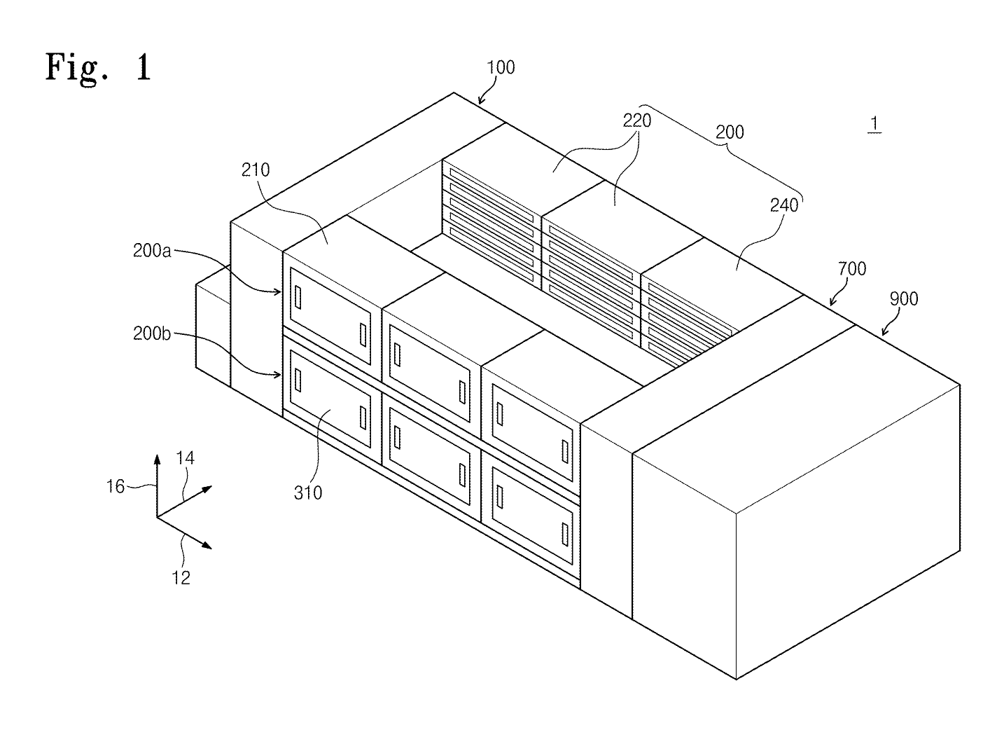

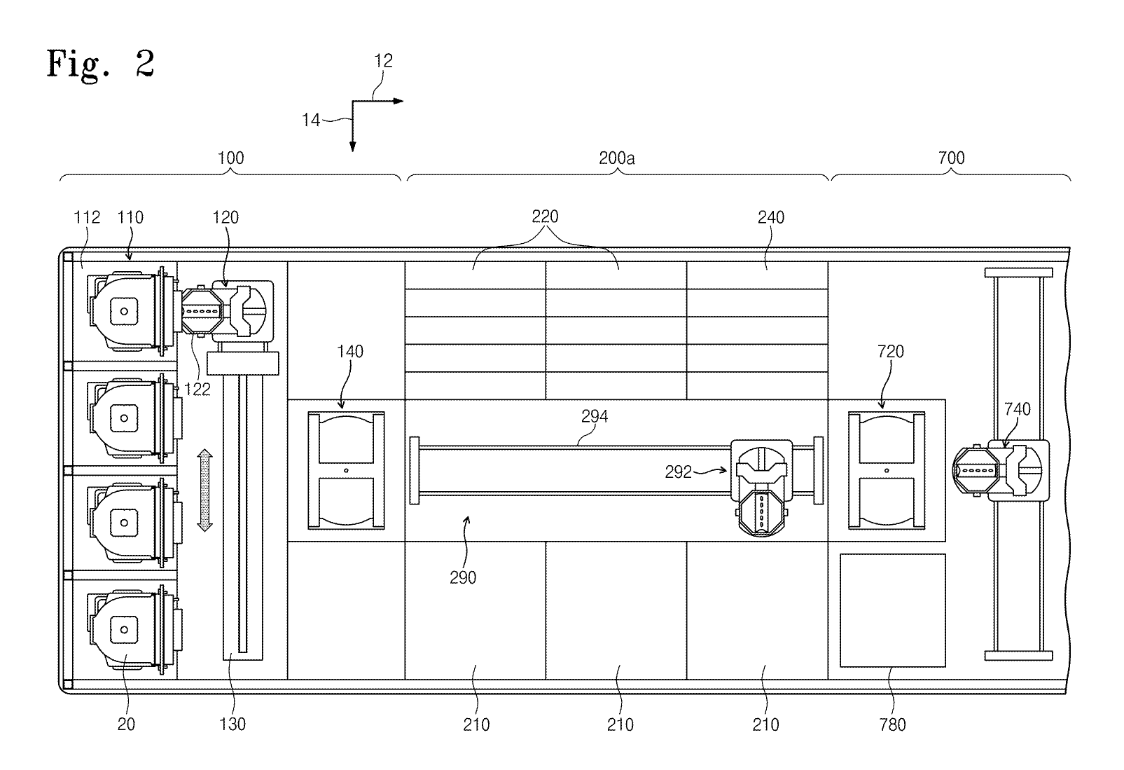

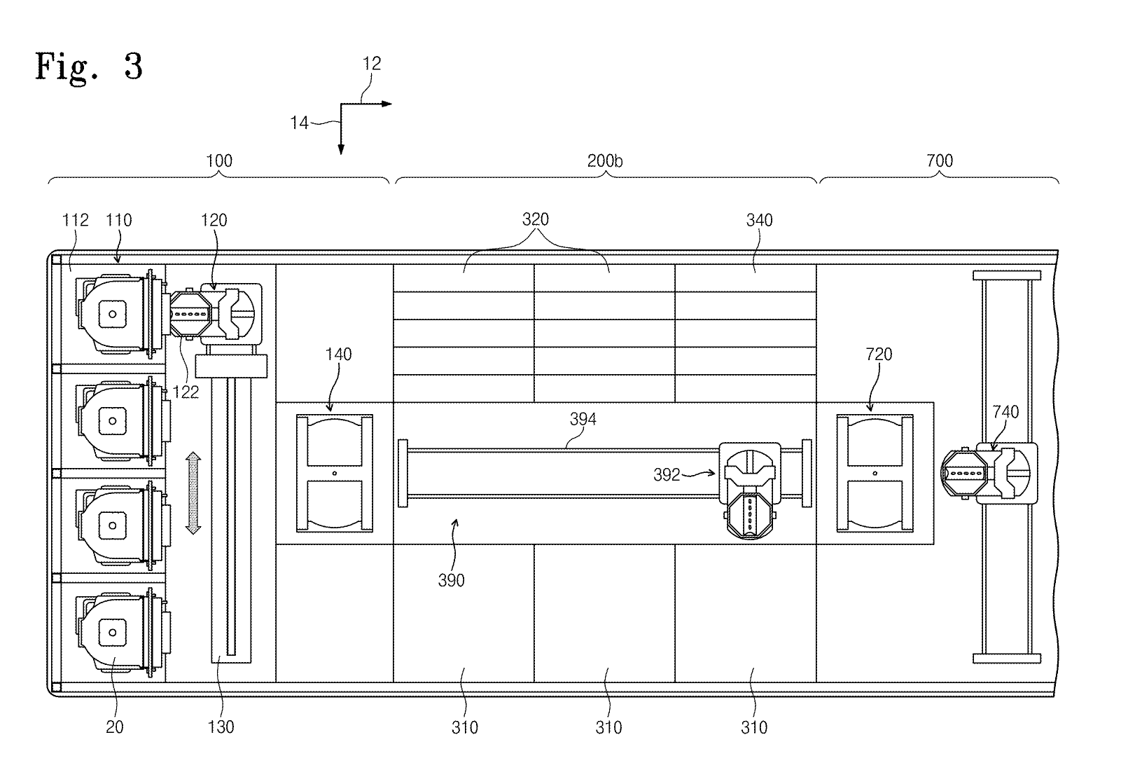

FIG. 1 is a perspective view illustrating photolithography equipment used in a wafer processing method according to an embodiment of the present invention. FIG. 2 is a view illustrating a coating process part of the photolithography equipment of FIG. 1, and FIG. 3 is a view illustrating a developing process part of the photolithography equipment of FIG. 1.

Referring to FIGS. 1 to 3, the photolithography equipment (hereinafter referred to as a wafer processing apparatus 1) includes an index part 100, a process part 200, an interface part 700, and an exposure device 900. The index part 100, the process part 200, and the interface part 700, and the exposure device 900 are sequentially arranged in a line in a predetermined direction.

Wafers (W) are carried in a state where the wafers (W) are contained in cassettes 20. The cassettes 20 can be hermetically closed. For example, the cassettes 20 may be front open unified pods (FOUPs) having front doors.

(Index Part)

The index part 100 includes a plurality of load ports 110, an index robot 120, and a first buffer module 140.

The load ports 110 include a stage 112 so that a cassette 20 in which wafers (W) are contained can be placed on the stage 112. The load ports 110 may include a plurality of stages 112. The stages 112 are arranged in a line in a second direction 14. In FIG. 2, four stages 112 are exemplarily shown.

The index robot 120 carries cassettes 20 between the stages 112 of the load ports 110 and the first buffer module 140. The index robot 120 includes a handle 122 having a four axis drive structure allowing rotation and movement in a first direction 12, the second direction 14, and a third direction 16. A guide rail 130 extends in the second direction 14. The index robot 120 is coupled to the guide rail 130 so that the index robot 120 can be linearly moved on the guide rail 130.

The first buffer module 140 has a hollow rectangular parallelepiped shape for temporarily storing a plurality of wafers (W) and is disposed between the index robot 120 and the process part 200.

(Process Part)

The process part 200 includes: a coating process part 200a for applying photoresist to wafers (W) before an exposure process; and a developing process part 200b for developing the wafers (W) after the exposure process.

The coating process part 200a and the developing process part 200b are arranged in different stages. For example, the coating process part 200a may be disposed above the developing process part 200b.

The coating process part 200a performs processes such as a process of applying a photosensitive material such as photoresist and a process of heating and cooling wafers (W) after applying photoresist to the wafers (W). The coating process part 200a includes coating modules 210, baking modules 220, cooling modules 240, and a transfer chamber 290.

The coating modules 210, the baking modules 220, the cooling modules 240, and the transfer chamber 290 may be sequentially arranged in the second direction 14. For example, the coating modules 210 may face the baking modules 220 and the cooling modules 240 with the transfer chamber 290 being disposed therebetween. The coating modules 210 may be arranged in the first direction 12 and the third direction 16. In the example shown in FIG. 3, three coating modules 210 are shown.

The transfer chamber 290 and the first buffer module 140 are arranged side by side in the first direction 12. A coating part robot 292 and a guide rail 294 are disposed in the transfer chamber 290. The transfer chamber 290 may have a rectangular shape. The coating part robot 292 moves wafers (W) among the baking modules 220, coating modules 210, cooling modules 240, and the first buffer module 140. The guide rail 294 extends in the first direction 12. The guide rail 294 guides linear motions of the coating part robot 292 in the first direction 12.

The coating modules 210 have the same structure. However, the coating modules 210 may use different kinds of photoresist. For example, chemical amplification resist may be used as photoresist. The coating modules 210 apply photoresist to wafers (W). The coating modules 210 perform an edge bead removal (EBR) process in which a thinner is sprayed to edge portions of wafers (W) while rotating the wafers (W) so as to remove beads from the edge portions of the wafers (W).

The baking modules 220 perform a heat treatment process on wafers (W). For example, the baking modules 220 may perform processes such as a prebaking process in which wafers (W) are heated to a predetermined temperature to remove organic materials and moisture from the wafers (W) before photoresist is applied to the wafers (W) and a soft baking process in which wafers (W) are heated after photoresist is applied to the wafers (W), and the baking modules 220 may perform a cooling process after each heat treatment process.

The developing process part 200b performs processes such as a developing process in which a developer is applied to wafers (W) to remove portions of photoresist from the wafers (W) to form patterns on the wafers (W) and a heat treatment process in which wafers (W) are cooled or heated before and after the developing process.

The developing process part 200b includes developing modules 310, baking modules 320, cooling modules 340, and a transfer chamber 390.

The developing modules 310, the baking modules 320, the cooling modules 340, and the transfer chamber 390 are sequentially arranged in the second direction 14. For example, the developing modules 310 may face the baking modules 320 and the cooling modules 340 with the transfer chamber 390 being disposed therebetween. The developing modules 310 may be arranged in the first direction 12 and the second direction 14. In the example shown in FIG. 3, three developing modules 310 are shown.

The transfer chamber 390 and the first buffer module 140 are arranged side by side in the first direction 12. A developing part robot 392 and a guide rail 394 are disposed in the transfer chamber 390. The transfer chamber 390 may have a rectangular shape. The developing part robot 392 moves wafers (W) among the baking modules 320, the developing modules 310, the cooling modules 340, and the first buffer module 140. The guide rail 394 extends in the first direction 12. The guide rail 394 guides linear motions of the developing part robot 392 in the first direction 12.

The developing modules 310 have the same structure. However, the developing modules 310 may use different kinds of developers. For example, portions of photoresist of wafers (W) exposed to light are removed in the developing modules 310. At this time, portions of protection layers exposed to light are also removed. Alternatively, according to the kind of photoresist, portions of photoresist and portions of protection layers that are not exposed to light may be removed.

The baking modules 320 perform a heat treatment process on wafers (W). For example, the baking modules 320 may perform processes such as a post-baking process in which wafers (W) are heated before a developing process, a hard baking process in which wafers (W) are heated after a developing process, and a cooling process after each baking process.

(Interface Part)

The interface part 700 carries wafers (W) between the process part 200 and the exposure device 900. The interface part 700 includes a first buffer module 720 and an interface robot 740. The interface robot 740 carries wafers (W) between the first buffer module 720 and the exposure device 900. The interface part 700 includes an edge exposure unit 800 disposed at a side thereof. The edge exposure unit 800 may perform an edge exposure of wafer (EEW) process by radiating an ultraviolet ray and an EBR process, so as to remove an edge portion of a photoresist layer formed on a semiconductor wafer, and the edge exposure unit 800 may perform a process of inspecting the result of an EEW process.

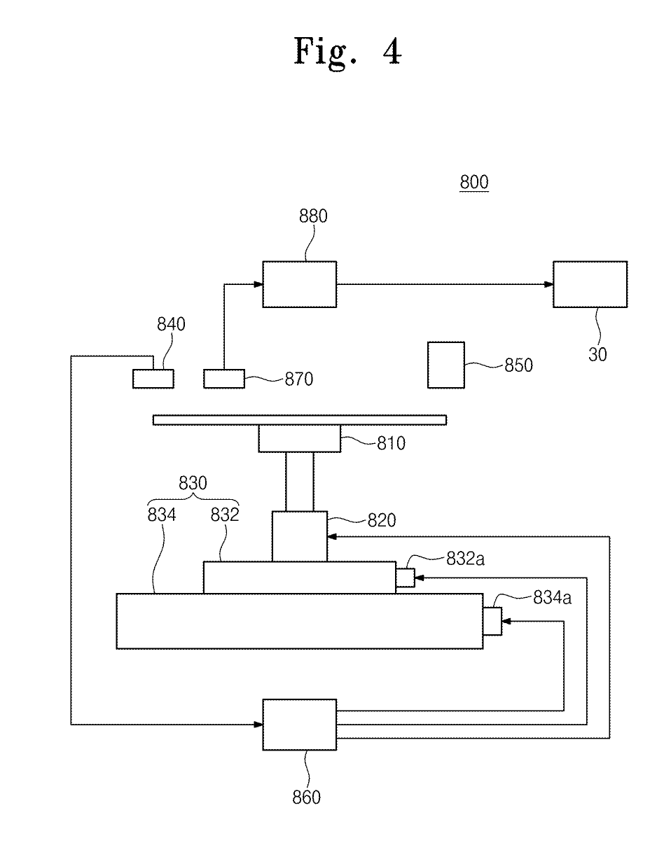

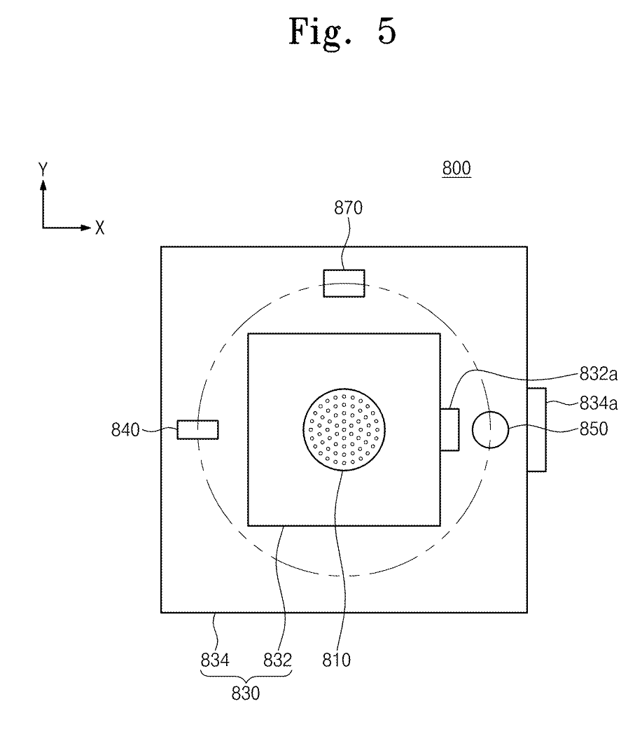

FIGS. 4 and 5 are views illustrating the edge exposure unit 800.

Referring to FIGS. 4 and 5, the edge exposure unit 800 includes a support plate 810, a rotary device 820, a moving device 830, an eccentricity detecting device 840, an ultraviolet radiation device 850, a driving control device 860, an imaging device 870, and an image process device 880.

The support plate 810 firmly holds a wafer (W) by forming a vacuum. The rotary device 820 is coupled to the bottom side of the support plate 810 to horizontally rotate the support plate 810. The moving device 830 is coupled to the bottom side of the rotary device 820 to horizontally move the rotary device 820; the eccentricity detecting device 840 detects the edge of the wafer (W) fixed to the support plate 810; the ultraviolet radiation device 850 is used to perform an exposure process on an edge portion of the wafer (W) fixed to the support plate 810; and the driving control device 860 controls operations of the rotary device 820 and the moving device 830.

The support plate 810 is a vacuum chuck for fixing a wafer (W) by creating a vacuum. Although not shown, the support plate 810 includes: a vacuum chuck body for placing a wafer (W) on the top surface thereof; a plurality of vacuum suction holes formed in the vacuum chuck body; and a vacuum line connected between the vacuum suction holes and a vacuum pump disposed outside the vacuum chuck body. A solenoid valve is disposed at the vacuum line to adjust a vacuum force of the vacuum chuck body, and a pressure valve is also disposed at the vacuum line to detect the vacuum force.

The rotary device 820 is coupled to the bottom side of the support plate 810 on which a wafer (W) is fixed. The rotary device 820 rotates the support plate 810. The rotary device 820 may include a rotary motor having a rotation shaft. The rotary device 820 is controlled by the driving control device 860.

The moving device 830 is coupled to the bottom side of the rotary device 820. The moving device 830 horizontal moves the support plate 810. The moving device 830 includes: an x-axis moving device 832 for horizontally reciprocating the rotary device 820 in an x-axis direction; and a y-axis moving device 834 for horizontally reciprocating the rotary device 820 in a y-axis direction. For example, the rotary device 820 may be slid back and forth on the x-axis moving device 832 in the x-axis direction, and the x-axis moving device 832 may be slid back and forth on the y-axis moving device 834 in the y-axis direction. The x-axis moving device 832 includes an x-axis driving motor 832a, and the y-axis moving device 834 includes a y-axis driving motor 834a. The x-axis driving motor 832a and the y-axis driving motor 834a are driven according to control signals from the driving control device 860 (described later).

The eccentricity detecting device 840 detects the eccentricity of a wafer (W) placed on the support plate 810. The eccentricity detecting device 840 includes a charge coupled device (CCD) to detect the edge of a wafer (W) while the wafer (W) is rotated once by the rotary device 820. Based on edge variations of a wafer (W) detected by the CCD while the wafer (W) is rotated once, the eccentricity detecting device 840 detects the center of the wafer (W). That is, the eccentricity detecting device 840 detects the center of the wafer (W) based on variations of the distance between the edge of the wafer (W) and the center of the rotary device 820.

The ultraviolet radiation device 850 exposes an edge portion of a wafer (W) to an ultraviolet ray. The ultraviolet radiation device 850 casts an ultraviolet ray to a photoresist layer formed on an edge portion of the topside of a wafer (W) to remove the photoresist layer from the edge portion.

The driving control device 860 controls the rotary device 820 and the moving device 830. The driving control device 860 controls the rotary device 820 and the moving device 830 so that a wafer (W) can be horizontally rotated on a center of the wafer (W) detected by the eccentricity detecting device 840. That is, the driving control device 860 synchronizes operations of the x-axis moving device 832 and the y-axis moving device 834 with rotation of a wafer (W) centered on the center of the wafer (W) so as to rotate the wafer (W) on its center.

The imaging device 870 includes a camera for obtaining images from an edge portion of a wafer (W) placed on the support plate 810. The camera may be an area camera capable of taking images from a bead removal region and an edge exposure region of an edge portion of a wafer (W) by an area scan method. The imaging device 870 is fixed to a position where the imaging device 870 can take images from an edge portion of a wafer (W) placed on the support plate 810.

While a wafer (W) is rotated once for measuring the eccentricity of the wafer (W), the imaging device 870 takes images from an edge portion of the wafer (W). The imaging device 870 takes first images from a wafer (W) while the wafer (W) is rotated once in an eccentricity measuring process and takes second images while the wafer (W) is rotated once after an EEW process. The first images are used to check whether beads are removed from an edge portion of the wafer (W), and the second images are used to check the result of the EEW process.

Although the imaging device 870 can take first images (or second images) continuously while a wafer (W) is rotated once, this delays data processing of the image process device 880 and requires a larger memory space. Thus, the imaging device 870 may take first images discontinuously while a wafer (W) is rotated once. For example, while a wafer (W) is rotated once, the imaging device 870 may take totally twelve first images by taking an image each time the wafer (W) is rotated thirty degrees.

The image process device 880 receives first and second images from the imaging device 870. The image process device 880 detects particles and the width of a bead removal region or an edge exposure region by processing the received images. The image process device 880 may check whether beads are removed from an edge portion of a wafer (W) based on the width of the bead removal region detected from the first images. The image process device 880 may check the exposed state of the edge portion of the wafer (W) based on the width of the edge exposure region detected from the second images.

Calculation results of the image process device 880 are transmitted to an upper level controller: a controller 30 of the wafer processing apparatus 1. The wafer processing apparatus 1 may correct factors such as robot twist amounts at the coating modules 210 that perform an EBR process, a nozzle position from which a thinner is injected to a wafer (W), and a wafer position at the edge exposure unit 800.

An edge exposure region of a wafer (W) means a region from which a photoresist layer is removed through an EEW process and an EBR process. Since the width of an EBR region is smaller than the width of an EEW region, a process of inspecting the width of an EBR region is performed before an EEW process. Although not shown, the imaging device 870 and the image process device 880 for inspecting whether beads are removed from a wafer (W) may be provided as a separate unit at the process part 200 instead of being provided at the edge exposure unit 800. That is, a unit for inspecting whether beads are removed from a wafer (W) may be provided at the process part 200. The unit may include a rotatable support plate on which a wafer (W) can be placed, an imaging device capable of taking images from an edge portion of a wafer (W); and an image process device.

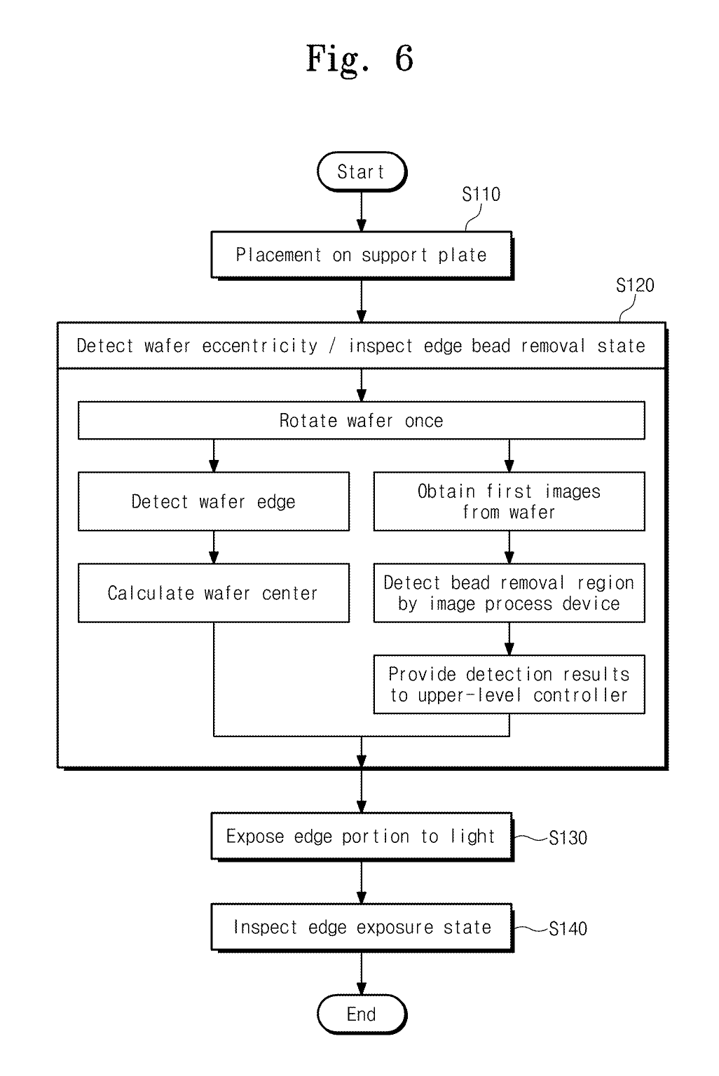

FIG. 6 is a flowchart for explaining a method for exposing a wafer edge portion.

The method is performed using the edge exposure unit 800 and includes: a process S110 of placing a wafer (W) on the support plate 810; a process S120 of detecting the eccentricity of the wafer (W) and inspecting whether beads are removed from an edge portion of the wafer (W); a process S130 of exposing the edge portion of the wafer (W) to an ultraviolet ray using the ultraviolet radiation device 850; and a process S140 of inspecting the exposed state of the edge portion of the wafer (W) after the process S130.

—Process S110 of Placing Wafer on Support Plate—

A wafer (W) is carried to the edge exposure unit 800 by a wafer transfer robot, and the wafer (W) is loaded on the support plate 810 and firmly held on the support plate 810 by vacuum suction. At this time, the center of the wafer (W) may not be precisely aligned with the rotation axis of the support plate 810.

—Process S120 of Detecting Eccentricity of Wafer and Inspecting Bead Removal State of Wafer—

The wafer (W) placed on the support plate 810 is rotated once. While the wafer (W) is rotated once, the eccentricity detecting device 840 detects the center of the wafer (W) based on variations of the edge of the wafer (W) detected by the CCD. While the wafer (W) is rotated once so that the eccentricity detecting device 840 detects the eccentricity of the wafer (W), the imaging device 870 discontinuously captures first images from the wafer (W) and provides the first images to the image process device 880.

The image process device 880 processes the first images received from the imaging device 870 so as to detect the width of an EBR region and detect particles. The image process device 880 checks whether beads are removed from the edge portion of the wafer (W) based on the width of the EBR region detected from the first images. Calculation results of the image process device 880 are provided to an upper-level controller: the controller 30 of the wafer processing apparatus 1.

—Process S130 of Exposing Wafer Edge Portion—

The wafer (W) is rotated on the center of the wafer (W) detected in process S120, and while the wafer (W) is rotated, the ultraviolet radiation unit 850 exposes the edge portion of the wafer (W) to an ultraviolet ray. The driving control device 860 controls the rotary device 820 and the moving device 830 so that a constant width of the edge portion of the wafer (W) can be exposed to the ultraviolet ray emitted from the eccentricity detecting device 840 without deviation. The driving control device 860 may synchronize operations of the x-axis moving device 832 and the y-axis moving device 834 with rotation of the wafer (W) by the support plate 810 so that the wafer (W) can be rotated on its center.

—Process S140 of Inspecting Edge Exposure State—

After the wafer edge exposure process, the wafer (W) placed on the support plate 810 is rotated once again. While the wafer (W) is rotated once, the imaging device 870 discontinuously captures second images from the wafer (W) and provides the second images to the image process device 880. The image process device 880 processes the second images received from the imaging device 870 to detect the width of an EEW region. The image process device 880 checks the edge exposure state of the wafer (W) based on the width of the EEW region.

According to the present invention, the results of an EBR process and an EEW process can be checked.

Although embodiments have been described with reference to a number of illustrative embodiments thereof, it should be understood that numerous other modifications and embodiments can be devised by those skilled in the art that will fall within the spirit and scope of the present invention. Thus, the embodiments are to be considered illustrative, and not restrictive, and the spirit and scope of the present invention is not limited to the embodiments. Hence, the real protective scope of the present invention shall be determined by the technical scope of the accompanying claims, and the scope of the present invention is to be determined by the broadest permissible interpretation of the following claims and their equivalents.

What is claimed is:

1. A method for processing a wafer edge portion, the method comprising:
placing a wafer on a support plate;
inspecting a bead removal state of an edge portion of the wafer placed on the support plate; and
exposing the edge portion of the wafer placed on the support plate to light,
wherein the inspecting of the bead removal state is performed by capturing first images from the wafer placed on the support plate and inspecting the first images.

2. The method of claim 1, further comprising inspecting an edge exposure state of the wafer placed on the support plate after the exposing of the edge portion of the wafer,
wherein the inspecting of the edge exposure state is performed by capturing second images from the wafer placed on the support plate and inspecting the second images.

3. The method of claim 1, wherein the first images are continuously captured using an imaging camera fixed to a predetermined position while the wafer placed on the support plate is rotated once.

4. The method of claim 1, wherein the first images are discontinuously captured using an imaging camera fixed to a predetermined position while the wafer placed on the support plate is rotated once.

5. The method of claim 3, wherein the imaging camera is an area camera capable of capturing images by an area scan method.

6. The method of claim 3, wherein the inspecting of the bead removal state is performed by detecting particles and measuring a width of a bead removal region using the first images.

7. A method for processing a wafer edge portion, the method comprising:
removing beads from an edge portion of a wafer;
inspecting a bead removal state of the edge portion of the wafer;
exposing the edge portion of the wafer to light; and
inspecting an exposed state of the edge portion of the wafer,
wherein the inspecting of the bead removal state, the exposing of the edge portion, and the inspecting of the exposed state are performed using the same apparatus.

8. The method of claim 7, wherein the inspecting of the bead removal state is performed by obtaining a first image from the wafer and inspecting the first image, and
the inspecting of the exposed state is performed by obtaining a second image from the wafer and inspecting the second image.

9. A method for processing a wafer edge portion, the method comprising:
placing a wafer on a support plate; and
inspecting a bead removal state of an edge portion of the wafer placed on the support plate,
wherein the inspecting of the bead removal state is performed by capturing a first image from the edge portion of the wafer placed on the support plate and inspecting the first image.

10. The method of claim 9, further comprising exposing the edge portion of the wafer placed on the support plate to light after the inspecting of the bead removal state.

11. The method of claim 10, further comprising inspecting an edge exposure state of the wafer placed on the support plate after the exposing of the edge portion of the wafer.

12. The method of claim 11, wherein the inspecting of the edge exposure state is performed by photographing the wafer placed on the support plate to obtain a second image different from the first image and inspecting the second image.

13. An apparatus for exposing a wafer edge portion to light, the apparatus comprising:
a support plate configured to support a wafer;
an eccentricity detecting device configured to detect eccentricity of the wafer placed on the support plate;
an imaging device configured to capture first images from an edge portion of the wafer placed on the support plate;
an ultraviolet radiation device configured to irradiate the edge portion of the wafer with an ultraviolet ray; and
an image process device configured to receive the first images from the imaging device so as to detect a width of a bead removal region.

14. The apparatus of claim 13, wherein the imaging device discontinuously captures the first images from the edge portion of the wafer while the wafer is rotated.

15. The apparatus of claim 13, wherein the eccentricity detecting device comprises a charge coupled device (CCD), and
the imaging device comprises an area camera configured to capture images by an area scan method.

16. A wafer processing apparatus comprising:
an index part comprising a load port and an index robot, the load port being configured to receive a wafer-containing cassette;
a process part connected to the index part, the process part comprising a coating process part for applying photoresist to a wafer and a developing process part for developing the wafer after an exposure process;
an interface part configured to carry a wafer between the process part and an exposure device configured to perform an exposure process on a wafer; and
an edge exposure unit configured to expose an edge portion of a wafer to light and inspect a bead removal state of the edge portion of the wafer.

17. The wafer processing apparatus of claim 16, wherein the edge exposure unit is disposed at the interface part or the process part.

18. The wafer processing apparatus of claim 16, wherein the edge exposure unit comprises:
a support plate configured to support a wafer;
an eccentricity detecting device configured to detect eccentricity of the wafer placed on the support plate;
an imaging device configured to capture first images from an edge portion of the wafer placed on the support plate;
an ultraviolet radiation device configured to irradiate the edge portion of the wafer with an ultraviolet ray; and
an image process device configured to receive the first images from the imaging device so as to detect a width of a bead removal region.
